(19) United States
(12) Patent Application Publication
(10) Pub. No.: US 2026/0308452 A1
(43) Pub. Date: Oct. 8, 2026

(54) RESIN COMPOSITION, FILM, METAL-CLAD LAMINATE, AND CIRCUIT BOARD

(71) Applicant: KURARAY CO., LTD., Kurashiki-shi, Okayama (JP)

(72) Inventors: Hiroaki SUGII, Kurashiki-shi , OKAYAMA (JP); Motoi SHIRAGA, Kurashiki-shi , OKAYAMA (JP); Sayaka IDE, Kurashiki-shi , OKAYAMA (JP); Minoru ONODERA, Kurashiki-shi, OKAYAMA (JP)

(73) Assignee: KURARAY CO., LTD., Kurashiki-shi, Okayama (JP)

(21) Appl. No.: 19/483,717

(22) PCT Filed: May 13, 2024
(86) PCT No.: PCT/JP2024/017577

§ 371 Date: Nov. 12, 2025

(30) Foreign Application Priority Data
May 15, 2023 (JP) 2023-080082

(51) Int. Cl. C09K 19/38; B32B 15/09; C08K 3/26; H05K 1/03

(52) U.S. Cl. CPC C09K 19/3809; B32B 15/09; C08K 3/26; H05K 1/0353; B32B 2367/00; C08K 2201/003

(57) ABSTRACT

Provided is a resin composition allows formation of a film having a low dielectric dissipation factor in high frequency bands, as well as having reduced thickness unevenness. The resin composition containing a thermoplastic liquid crystal polymer, wherein the resin composition has a dielectric dissipation factor of 0.0015 or less at 5 GHz, and has a percent decrease of a complex viscosity η* of 20% or less, where the complex viscosity η* is measured using a rotational rheometer, and the percent decrease of the complex viscosity η* is calculated from a value measured at a point when a frequency of the rotational rheometer is changed to 100 rad/s following 12 minutes of an operation at 1 rad/s, and a value measured 7 minutes after the point of frequency change.

### CROSS REFERENCE TO THE RELATED APPLICATION

This application is based on and claims Convention priority to Japanese patent application No. 2023-080082, filed May 15, 2023, the entire disclosure of which is herein incorporated by reference as a part of this application.

### FIELD OF THE INVENTION

The present invention relates to a resin composition containing a polymer capable of forming an optically anisotropic molten phase (hereinafter, referred to as thermoplastic liquid crystal polymer). The present invention also relates to a film including the resin composition, a metal-clad laminate including the film and a metal layer bonded to at least one surface of the film, and a circuit board at least including an insulating layer containing the resin composition and a conductor layer.

### BACKGROUND OF THE INVENTION

In recent years, there has been remarkable development in the field of information processing devices, communication devices, and the like, and with accelerated signal transmission for circuits used in these fields, signals having higher frequencies are increasingly used. In response to such development, substrates for circuit boards are required to have excellent dielectric characteristics in high frequency regions.

As a material excellent in dielectric characteristics in high frequency regions (high frequency characteristics), a thermoplastic liquid crystal polymer has been increasingly attracting attention. For example, Patent Document 1 (JP Patent No. 4639756) discloses an aromatic liquid crystal polyester contains 40 to 74.8 mol % of a repeating unit derived from 2-hydroxy-6-naphthoic acid, 12.5 to 30 mol % of a repeating unit derived from hydroquinone or 4,4′-dihydroxybiphenyl, 12.5 to 30 mol % of a repeating unit derived from 2,6-naphthalenedicarboxylic acid, and 0.2 to 15 mol % of a repeating unit derived from terephthalic acid or 4,4′-biphenyldicarboxylic acid, in which the number of moles of the repeating unit derived from terephthalic acid or 4,4′-biphenyldicarboxylic acid is equal to or more than the number of moles of the repeating unit derived from 2,6-naphthalenedicarboxylic acid, and the aromatic liquid crystal polyester has a flow start temperature of 300 to 400° C. This document also describes that this aromatic liquid crystal polyester has a small dielectric loss and is excellent in processability for forming a film shape.

### CONVENTIONAL ART DOCUMENT

### Patent Document

[Patent Document 1] JP Patent No. 4639756

### SUMMARY OF THE INVENTION

### Problems to be Solved by the Invention

However, the aromatic liquid crystal polyester described in Examples of Patent Document 1 makes it possible to form a film exhibiting a low dielectric dissipation factor, but there is a problem that the film formed from such an aromatic liquid crystal polyester has thickness unevenness as an appearance defect.

Therefore, an object of the present invention is to provide a thermoplastic liquid crystal polymer resin composition allows formation of a film having a low dielectric dissipation factor in high frequency bands, as well as having reduced thickness unevenness, which is an appearance defect.

Another object of the present invention is to provide a film including the resin composition, a metal-clad laminate including the film and a metal layer bonded to at least one surface of the film, and a circuit board including a conductor layer and an insulating layer containing the resin composition.

### Means for Solving the Problems

The inventors of the present invention have conducted extensive studies in order to achieve the aforementioned object, and found that a resin composition containing a thermoplastic liquid crystal polymer, which has a dielectric dissipation factor at 5 GHz in a specific range and has a percent decrease of a complex viscosity η* in a specific range, can be formed into a film that has excellent dielectric characteristics in the high frequency bands as well as has reduced thickness unevenness. The inventors thus achieved the present invention.

That is, the present invention may include the following aspects.

### [Aspect 1]

A resin composition containing a thermoplastic liquid crystal polymer, wherein the resin composition has a dielectric dissipation factor of 0.0015 or less (preferably, 0.0014 or less, more preferably 0.0013 or less, further preferably 0.0012 or less, further more preferably 0.0011 or less, and particularly preferably 0.0010 or less) at 5 GHz, and has a percent decrease of a complex viscosity η* of 20% or less (preferably 19% or less, more preferably 18% or less, further preferably 15% or less, and further more preferably 10% or less) where the complex viscosity if is measured using a rotational rheometer under the following measurement conditions, and the percent decrease of the complex viscosity η* is calculated from a value measured at a point when a frequency of the rotational rheometer is changed to 100 rad/s following 12 minutes of an operation at 1 rad/s, and a value measured 7 minutes after the point of frequency change,

### (Measurement Conditions)

parallel plate measurement,
gap distance: 0.9 mm,
plate diameter: 25 mm,
measurement temperature: Tm₁+20° C., in which Tm₁ denotes an endothermic peak temperature attributed to the thermoplastic liquid crystal polymer measured using a differential scanning calorimeter,
strain: 3.0%,
soak time during each of measurements at the frequencies of 1 rad/s and 100 rad/s: 0.0 seconds,
sampling interval during measurement at the frequency of 100 rad/s: 5.0 s/pt, and
preheating time: 5 minutes.

### [Aspect 2]

The resin composition according to aspect 1, wherein the resin composition has a melt viscosity of 30 to 120 Pa·s (preferably 35 to 80 Pa·s, more preferably 40 to 70 Pa·s, further preferably 42 to 65 Pa·s), where the melt viscosity is measured using a capillary rheometer under the following conditions: a capillary diameter of 1.0 mm, a capillary length of 20 mm, a temperature of the endothermic peak temperature Tm₁+20° C., a shear rate of 1000 sec⁻¹, and a preheating time of 5 minutes.

### [Aspect 3]

The resin composition according to aspect 1 or 2, wherein the resin composition has a melt tension of 0.002 N or more (preferably 0.003 N or more and more preferably 0.004 N or more), where the melt tension is measured using a capillary rheometer by taking up the resin composition at a speed of 30 m/min, with a distance from a capillary outlet to a center position of a tension pulley set at 200 mm, under the following conditions: a capillary diameter of 1.0 mm, a capillary length of 20 mm, a temperature of the endothermic peak temperature Tm₁+20° C., a shear rate of 1000 sec⁻¹, and a preheating time of 5 minutes.

### [Aspect 4]

The resin composition according to any one of aspects 1 to 3, wherein the resin composition has a difference Tm₁− Tm₆ of 12° C. or less (preferably 10° C. or less, more preferably 9° C. or less, and further preferably 8° C. or less), where Tm₁ denotes an endothermic peak temperature during a first heating run, and Tm₆ denotes an endothermic peak temperature during a sixth heating run, when a heating and cooling cycle is repeated using a differential scanning calorimeter under the following heating and cooling conditions:

### (Heating and Cooling Conditions)

heating condition: a temperature is increased from 25° C. to 400° C. at a rate of 20° C./min, and is maintained for 2 minutes after the temperature reaches 400° C., and
cooling condition: a temperature is decreased from 400° C. to 25° C. at a rate of 20° C./min, and is maintained for 2 minutes after the temperature reaches 25° C.

### [Aspect 5]

The resin composition according to any one of aspects 1 to 4, wherein the resin composition has a ratio Y/X of 1.30 or less (preferably 1.25 or less and more preferably 1.20 or less), where X denotes a melt viscosity (Pa·s) measured using a capillary rheometer under the following conditions: a capillary diameter of 1.0 mm, a capillary length of 20 mm, a temperature of the endothermic peak temperature Tm₁+20° C., a shear rate of 1000 sec⁻¹, and a preheating time of 5 minutes, and Y denotes a melt viscosity (Pa·s) subsequently measured under conditions of the same temperature and shear rate after the resin composition is allowed to stand at the same temperature in a barrel of the capillary rheometer for 30 minutes.

### [Aspect 6]

The resin composition according to any one of aspects 1 to 5, wherein based on a total content of all repeating units in the thermoplastic liquid crystal polymer, a molar proportion of a repeating unit represented by the following formula (1) is 0 to 25 mol % (preferably 0.1 to 25 mol % and more preferably 1 to 20 mol %), a molar proportion of a repeating unit represented by the following formula (2) is 25 to 90 mol % (preferably 25 to 80 mol % and more preferably 30 to 75 mol %), a molar proportion of a repeating unit represented by the following formula (3) is 0.1 to 40 mol % (preferably 0.1 to 37.5 mol %, more preferably 1 to 35 mol %, and further preferably 5 to 30 mol %), and a molar proportion of a repeating unit represented by the following formula (4) is 0.1 to 40 mol % (preferably 0.1 to 37.5 mol %, more preferably 1 to 35 mol %, and further preferably 5 to 30 mol %),

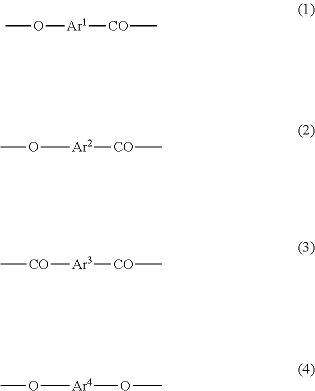

where Ar¹ is a 1,4-phenylene group, Ar² is a 2,6-naphthylene group, Ar³ is at least one selected from the group consisting of a 1,4-phenylene group, a 1,3-phenylene group, and a 2,6-naphthylene group, Ar⁴ is at least one selected from the group consisting of a 1,4-phenylene group, a 1,3-phenylene group, and a 4,4′-biphenylylene group, and hydrogen atoms of aromatic rings of Ar¹, Ar², Ar³, and Ar⁴ are each optionally independently substituted with at least one selected from the group consisting of a C₁₋₃ alkyl group, a halogen atom, and a phenyl group.

### [Aspect 7]

The resin composition according to aspect 6, wherein the thermoplastic liquid crystal polymer contains a total of 40 mol % or more (preferably 50 mol % or more and more preferably 60 mol % or more) of a repeating unit including a 2,6-naphthylene group based on the total content of all the repeating units.

### [Aspect 8]

The resin composition according to any one of aspects 1 to 7, containing particulate materials.

### [Aspect 9]

The resin composition according to any one of aspects 1 to 8, containing an additive material, wherein the additive material is at least one selected from the group consisting of a thermoplastic resin, a thermosetting resin, an inorganic compound, and a liquid crystalline oligomer.

### [Aspect 10]

The resin composition according to aspect 9, containing, as the thermoplastic resin, at least one selected from the group consisting of an amorphous polyarylate-based resin, a polyphenylene ether-based resin, a polyphenylene sulfide-based resin, a polyetherimide-based resin, a polyether sulfone-based resin, a polycarbonate-based resin, a polyether ether ketone-based resin, and a fluorine-based resin.

### [Aspect 11]

The resin composition according to aspect 9 or 10, containing, as the inorganic compound, at least one selected from the group consisting of silica and titanium oxide.

### [Aspect 12]

The resin composition according to any one of aspects 9 to 11, containing two or more types of inorganic particles having different median diameters from each other.

### [Aspect 13]

The resin composition according to any one of aspects 9 to 12, containing two or more types of the additive materials.

### [Aspect 14]

The resin composition according to any one of aspects 9 to 13, wherein a weight ratio (thermoplastic liquid crystal polymer/additive material) of the thermoplastic liquid crystal polymer to the additive material is in a range of from 63.0/37.0 to 94.9/5.1 (preferably from 66.0/34.0 to 94.5/5.5 and more preferably from 72.0/28.0 to 93.0/7.0).

### [Aspect 15]

A film including the resin composition as recited in any one of aspects 1 to 14.

### [Aspect 16]

The film according to aspect 15, having a thickness of 5 to 200 μm (preferably 10 to 150 μm).

### [Aspect 17]

The film according to aspect 15 or 16, having a coefficient of variation of thickness in a film width direction of 1.90% or less (preferably 1.80% or less, more preferably 1.75% or less, further preferably 1.70% or less, further more preferably 1.40% or less, and particularly preferably 1.30% or less) as measured using a continuous thickness gauge.

### [Aspect 18]

A metal-clad laminate including the film as recited in any one of aspects 15 to 17 and a metal layer bonded to at least one surface of the film.

### [Aspect 19]

A circuit board at least including a conductor layer, and an insulating layer containing the resin composition as recited in any one of aspects 1 to 14.

As used herein, the singular forms, “a,” “an”, and “the” are intended to include plural forms including “at least one”, unless the content clearly indicates otherwise. As used herein, the terms “and/or”, “at least one”, and “one or more” include any and all combinations of the relevant listed items.

Any combination of at least two constructions, disclosed in the appended claims and/or the specification should be construed as included within the scope of the present invention. In particular, any combination of two or more of the appended claims should be equally construed as included within the scope of the present invention.

### Effect of the Invention

The resin composition of the present invention allows formation of a film having a low dielectric dissipation factor in high frequency bands, as well as having reduced thickness unevenness.

The film including the resin composition of the present invention has a low dielectric dissipation factor in high frequency bands, and thus can be suitably used as a circuit board material and the like.

### DESCRIPTION OF EMBODIMENT

### [Thermoplastic Liquid Crystal Polymer]

A resin composition contains a thermoplastic liquid crystal polymer. The thermoplastic liquid crystal polymer is formed from a melt-processable liquid crystalline polymer (or a polymer capable of forming an optically anisotropic melt phase). Chemical formulation of the thermoplastic liquid crystal polymer is not particularly limited to a specific one as long as it is a melt-formable liquid crystalline polymer, and examples thereof may include a thermoplastic liquid crystal polyester, a thermoplastic liquid crystal polyester amide having an amide bond introduced thereto, or the like.

The thermoplastic liquid crystal polymer may also be a polymer obtained by further introducing, to an aromatic polyester or an aromatic polyester amide, an imide bond, a carbonate bond, a carbodiimide bond, or an isocyanate-derived bond such as an isocyanurate bond.

It should be noted that in the present specification, capability of forming an optically anisotropic melt phase can be determined by, for example, placing a sample on a hot stage, heating the sample with an elevating temperature under a nitrogen atmosphere, and observing light transmitted through the sample.

Specific examples of the thermoplastic liquid crystal polymer may include known thermoplastic liquid crystal polyesters and thermoplastic liquid crystal polyester amides obtained from compounds classified as (1) to (4) as exemplified in the following, and derivatives thereof. However, it is needless to say that, in order to form a polymer capable of forming an optically anisotropic melt phase, there is a suitable range regarding the combination of various raw-material compounds.

### (1) Aromatic or Aliphatic Diols (See Table 1 for Representative Examples)

TABLE 1
Chemical structural formulae of representative examples of
aromatic or aliphatic diols

| | |
|---|---|
| 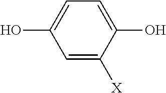 | X represents a hydrogen atom or a halogen atom, or a group such as a lower alkyl (e.g., C₁₋₃ alkyl) or a phenyl |
| 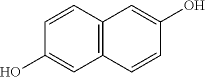 [SMILES: Oc1ccc2cc(O)ccc2c1] | 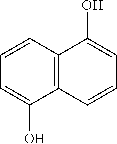 [SMILES: Oc1cccc2c(O)cccc12] |
| 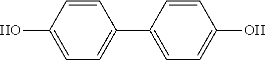 [SMILES: Oc1ccc(-c2ccc(O)cc2)cc1] | |
| 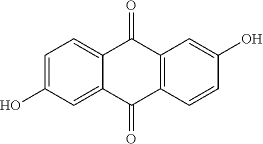 [SMILES: O=C1c2ccc(O)cc2C(=O)c2ccc(O)cc21] | 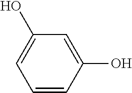 |
| 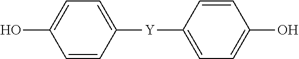 | Y represents a group such as —O—, —CH₂—, —S—, —CO—, —C(CH₃)₂—, or —SO₂— |
| HO(CH₂)ₙOH | n is an integer of 2 to 12 |

### (2) Aromatic or Aliphatic Dicarboxylic Acids (See Table 2 for Representative Examples)

TABLE 2
Chemical structural formulae of representative examples of
aromatic or aliphatic dicarboxylic acids

| | |
|---|---|
| 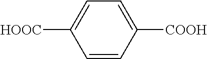 [SMILES: O=C(O)c1ccc(C(=O)O)cc1] | 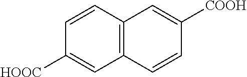 [SMILES: O=C(O)c1ccc2cc(C(=O)O)ccc2c1] |
| 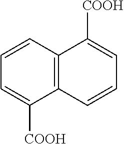 [SMILES: O=C(O)c1cccc2c(C(=O)O)cccc12] | 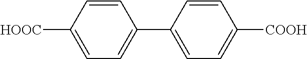 [SMILES: O=C(O)c1ccc(-c2ccc(C(=O)O)cc2)cc1] |
| 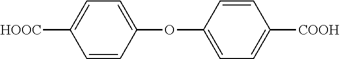 [SMILES: O=C(O)c1ccc(Oc2ccc(C(=O)O)cc2)cc1] | |
| 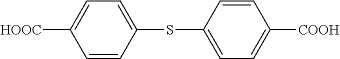 [SMILES: O=C(O)c1ccc(Sc2ccc(C(=O)O)cc2)cc1] | |
| 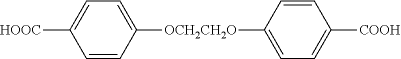 | |
| 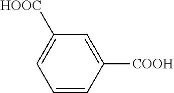 [SMILES: O=C(O)c1cccc(C(=O)O)c1] | |
| HOOC(CH₂)ₙCOOH | n is an integer of 2 to 12 |

### (3) Aromatic Hydroxycarboxylic Acids (See Table 3 for Representative Examples)

TABLE 3
Chemical structural formulae of representative examples of
aromatic hydroxycarboxylic acids

| | |
|---|---|
| 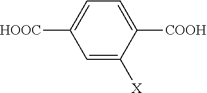 | X represents a hydrogen atom or a halogen atom, or a group such as a lower alkyl (e.g., C₁₋₃ alkyl) or a phenyl |
| 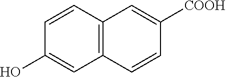 [SMILES: O=C(O)c1ccc2cc(O)ccc2c1] | 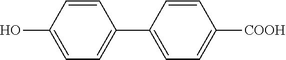 [SMILES: O=C(O)c1ccc(-c2ccc(O)cc2)cc1] |
| 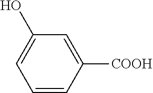 | |

### (4) Aromatic Diamines, Aromatic Hydroxy Amines, and Aromatic Aminocarboxylic Acids (See Table 4 for Representative Examples)

TABLE 4
Chemical structural formulae of representative examples of aromatic diamines,
aromatic hydroxy amines, or aromatic aminocarboxylic acids

| | | |
|---|---|---|
| 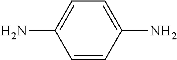 | 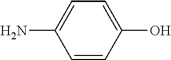 | 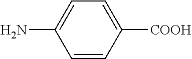 |

Representative examples of thermoplastic liquid crystal polymers obtained from these raw material compounds may include copolymers having repeating units shown in Tables 5 and 6.

TABLE 5
Representative examples (1) of thermoplastic liquid crystal polymer

| | |
|---|---|
| (A) | 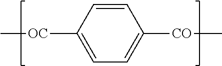 |
| | 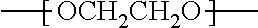 |
| | 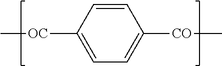 |
| (B) | 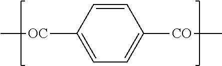 |
| | 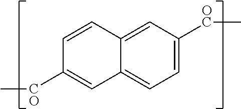 |
| | 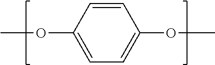 |
| (C) | 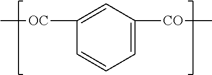 |
| | 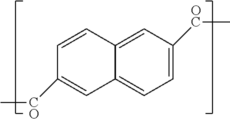 |
| | 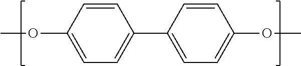 |
| (D) | 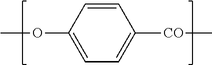 |
| | 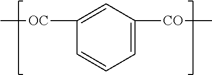 |
| | 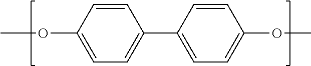 |
| (E) | 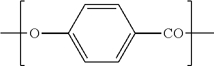 |
| | 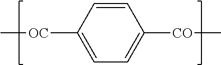 |
| | 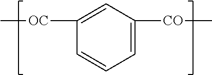 |
| | 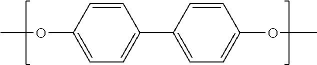 |
| (F) | 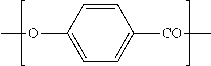 |
| | 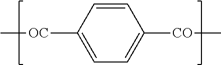 |
| | 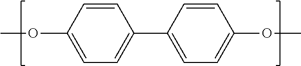 |
| | 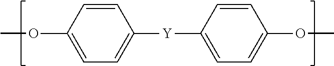 |
| | Y is a group such as —O—, —S—, or —CH₂— |
| (G) | 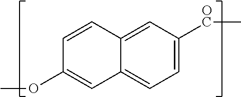 |
| | 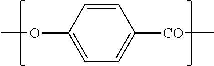 |
| (H) | 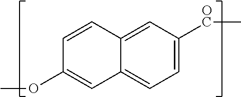 |
| | 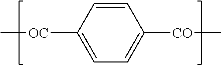 |
| | 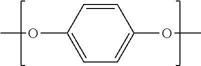 |
| (I) | 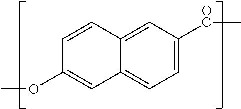 |
| | 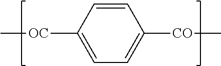 |
| | 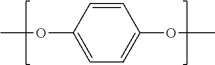 |
| | 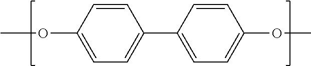 |
| (J) | 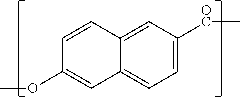 |
| | 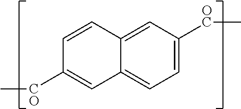 |
| | 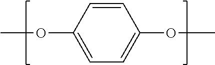 |

TABLE 6
Representative examples (2) of thermoplastic liquid crystal polymer

| | |
|---|---|
| (K) | 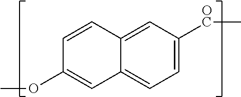 |
| | 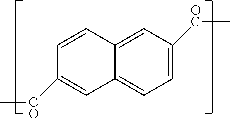 |
| | 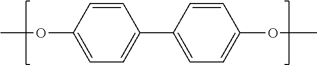 |
| (L) | 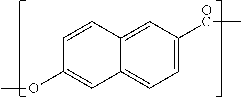 |
| | 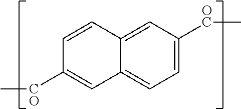 |
| | 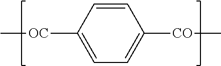 |
| | 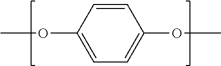 |
| (M) | 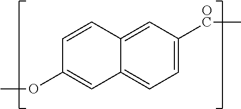 |
| | 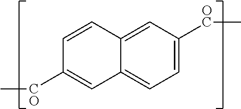 |
| | 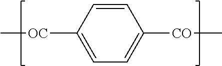 |
| | 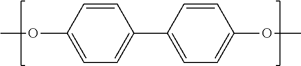 |
| (N) | 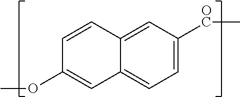 |
| | 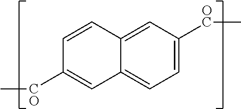 |
| | 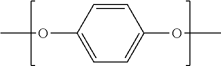 |
| | 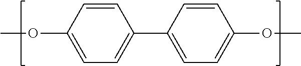 |
| (O) | 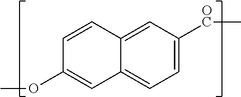 |
| | 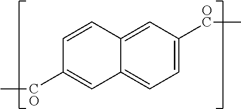 |
| | 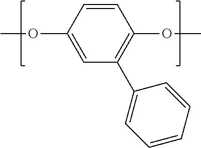 |
| | 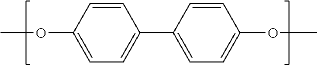 |
| (P) | 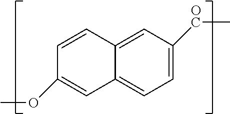 |
| | 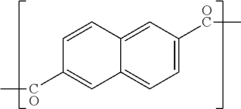 |
| | 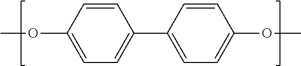 |
| | 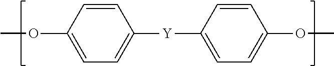 |
| | Y is a group such as —O—, —S—, or —CH₂— |
| (Q) | 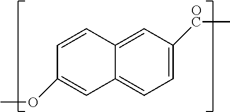 |
| | 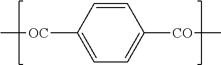 |
| | 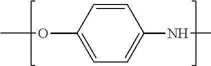 |

Examples of copolymers constituting the thermoplastic liquid crystal polymer include: a copolymer including repeating units derived from two or more aromatic hydroxycarboxylic acids; a copolymer including a repeating unit derived from at least one aromatic hydroxycarboxylic acid, a repeating unit derived from at least one aromatic dicarboxylic acid, and a repeating unit derived from at least one aromatic diol and/or aromatic hydroxy amine; and the like. For example, preferable copolymers include at least a repeating unit derived from p-hydroxybenzoic acid and/or 6-hydroxy-2-naphthoic acid as the repeating unit derived from the aromatic hydroxycarboxylic acid. The resin composition may contain a mixture that contains two or more copolymers, among these copolymers, in which combinations of repeating units and/or contents thereof are different from each other.

The thermoplastic liquid crystal polymer in the resin composition may preferably include the repeating unit derived from at least one aromatic hydroxycarboxylic acid, the repeating unit derived from at least one aromatic dicarboxylic acid, and the repeating unit derived from at least one aromatic diol and/or aromatic hydroxy amine. In the present specification, when two or more copolymers in which the combinations of repeating units and/or the contents thereof are different from each other are contained in the resin composition, the repeating units constituting the thermoplastic liquid crystal polymer in the resin composition are defined as all repeating units of all those copolymers. The content of each of repeating units constituting the thermoplastic liquid crystal polymer in the resin composition is defined as an average value calculated in consideration of the combination of repeating units of two or more copolymers and the contents and molecular weights thereof.

For example, based on a total content of all repeating units in the thermoplastic liquid crystal polymer in the resin composition, a molar proportion of a repeating unit represented by the following formula (1) (hereinafter, sometimes referred to as a repeating unit (1)) is 0 to 25 mol %, a molar proportion of a repeating unit represented by the following formula (2) (hereinafter, sometimes referred to as a repeating unit (2)) is 25 to 90 mol %, a molar proportion of a repeating unit represented by the following formula (3) (hereinafter, sometimes referred to as a repeating unit (3)) is 0.1 to 40 mol %, and a molar proportion of a repeating unit represented by the following formula (4)(hereinafter, sometimes referred to as a repeating unit (4)) is 0.1 to 40 mol %.

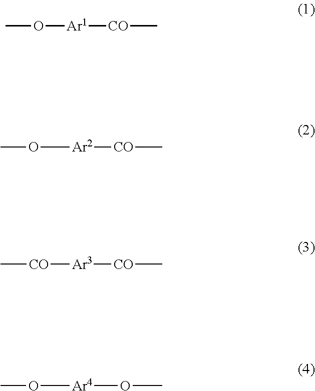

(where Ar¹ is a 1,4-phenylene group, Ar² is a 2,6-naphthylene group, Ar³ is at least one selected from the group consisting of a 1,4-phenylene group, a 1,3-phenylene group, and a 2,6-naphthylene group, Ar⁴ is at least one selected from the group consisting of a 1,4-phenylene group, a 1,3-phenylene group, and a 4,4′-biphenylylene group, and hydrogen atoms of aromatic rings of Ar¹, Ar², Ar³, and Ar⁴ are each optionally independently substituted with at least one selected from the group consisting of a C₁₋₃ alkyl group, a halogen atom, and a phenyl group.)

When the thermoplastic liquid crystal polymer in the resin composition includes the repeating unit (1), the content (molar proportion) of the repeating unit (1) may be preferably 0.1 to 25 mol % and more preferably 1 to 20 mol %, based on the total content of all the repeating units.

The content of the repeating unit (2) in the thermoplastic liquid crystal polymer in the resin composition may be preferably 25 to 80 mol % and more preferably 30 to 75 mol %, based on the total content of all the repeating units.

The content of the repeating unit (3) in the thermoplastic liquid crystal polymer in the resin composition may be preferably 0.1 to 37.5 mol %, more preferably 1 to 35 mol %, and further preferably 5 to 30 mol %, based on the total content of all the repeating units.

The content of the repeating unit (4) in the thermoplastic liquid crystal polymer in the resin composition may be preferably 0.1 to 37.5 mol %, more preferably 1 to 35 mol %, and further preferably 5 to 30 mol %, based on the total content of all the repeating units.

From the viewpoint of making it easier to increase a molecular weight of the thermoplastic liquid crystal polymer to improve the mechanical properties, a molar ratio of the repeating unit (3) to the repeating unit (4), expressed as (3)/(4), in the thermoplastic liquid crystal polymer in the resin composition may be 95/100 to 100/95, preferably 98/100 to 100/98, more preferably 99/100 to 100/99, and further preferably 100/100.

From the viewpoint of reducing the dielectric dissipation factor, the thermoplastic liquid crystal polymer in the resin composition preferably includes a repeating unit having a naphthalene skeleton. For example, a total content of a repeating unit including a 2,6-naphthylene group in the thermoplastic liquid crystal polymer in the resin composition may be 40 mol % or more, preferably 50 mol % or more, and more preferably 60 mol % or more, based on the total content of all the repeating units. From the viewpoint of adjusting a melting point to improve melt-formability, the total content of the repeating unit may be 95 mol % or less, preferably 90 mol % or less, and more preferably 85 mol % or less. As the repeating unit including the 2,6-naphthylene group, the repeating unit (2) (repeating unit derived from 6-hydroxy-2-naphthoic acid) and the repeating unit (3) in which Ar³ is a 2,6-naphthylene group (repeating unit derived from 2,6-naphthalenedicarboxylic acid) are preferable.

The thermoplastic liquid crystal polymer in the resin composition may include two or more types of each of the repeating units (1) to (4). The content of each repeating unit represents the total content of all repeating units corresponding to the repeating unit. For example, in the case where the thermoplastic liquid crystal polymer in the resin composition includes two types of repeating unit (3) which are a repeating unit in which Ar³ is a 1,4-phenylene group and a repeating unit in which Ar³ is a 2,6-naphthylene group, the content of the repeating unit (3) represents the total content thereof.

The thermoplastic liquid crystal polymer in the resin composition may include two or more types of the repeating unit (3) and/or two or more types of the repeating unit (4).

The thermoplastic liquid crystal polymer in the resin composition may have a repeating unit other than the repeating units (1) to (4), but the total content of the repeating units (1) to (4) based on the total content of all the repeating units may be, for example, 95 mol % or more, preferably 98 mol % or more, more preferably 99 mol % or more, and further preferably 100 mol %.

The thermoplastic liquid crystal polymer can be synthesized by a known polycondensation method. Examples of monomers for polycondensation may include various aromatic diols, aromatic dicarboxylic acids, aromatic hydroxycarboxylic acids, and aromatic hydroxy amines, and hydroxy group acylates and carboxylic acid derivatives such as carboxyl group esters, acid halides, and acid anhydrides by activating the end thereof.

Polycondensation may be performed in the presence of various polymerization catalysts, such as organotin-based catalysts (dialkyl tin oxide, etc.), antimony-based catalysts (antimony trioxide, etc.), titanium-based catalysts (titanium dioxide, etc.), alkali metal salts or alkaline earth metal salts of carboxylic acids (potassium acetate, etc.), Lewis acids (BF₃, etc.), organic compound catalysts (N,N-dimethylaminopyridine, 1-methylimidazole, etc.), and the like.

After polycondensation is performed by polymerization in the melt phase, solid-phase polymerization may be further performed. Solid-phase polymerization can be performed by a method, for example, in which the polymer thus obtained through the melt-polymerization step is crushed into a powder shape or a flake shape, or is granulated by an extruder into a pellet shape, and then, is subjected to heat treatment in the solid phase under vacuum or under an inert atmosphere such as nitrogen.

### [Resin Composition]

The resin composition has a dielectric dissipation factor of 0.0015 or less at 5 GHz, and has a percent decrease of a complex viscosity η* of 20% or less. Such a resin composition allows formation of a film having excellent dielectric characteristics in high frequency bands, as well as having reduced thickness unevenness.

The inventors of the present invention have found a problem that when a film is formed from a conventional thermoplastic liquid crystal polymer having a low dielectric dissipation factor in high frequency bands, the obtained film tends to have film thickness unevenness. A cause of this problem is considered as follows. That is, the thermoplastic liquid crystal polymer having a low dielectric dissipation factor according to the conventional art tends to have weak polarization in a molecular chain direction, and in such a thermoplastic liquid crystal polymer, a liquid crystal domain, which is a region where molecular chains are oriented and aligned, becomes less stable under shear during film formation, which causes occurrence of film thickness unevenness as an appearance defect of the formed film. Thus, it has been found that there is a trade-off relationship that characteristics of the thermoplastic liquid crystal polymer exhibiting the low dielectric dissipation factor in the high frequency bands are disadvantageous in the film formation. The inventors of the present invention have found that stability of the liquid crystal domain under shear of the thermoplastic liquid crystal polymer correlates with the percent decrease of the complex viscosity η*, and by adjusting the percent decrease of the complex viscosity η* in the resin composition containing the thermoplastic liquid crystal polymer to a specific range, the resin composition which exhibits the low dielectric dissipation factor in the high frequency bands, as well as which has high stability in the liquid crystal domain even under shear, and allows formation of a film with reduced thickness unevenness, can be obtained.

In the resin composition, the dielectric dissipation factor at 5 GHz may be preferably 0.0014 or less, more preferably 0.0013 or less, further preferably 0.0012 or less, further more preferably 0.0011 or less, particularly preferably 0.0010 or less, and particularly more preferably 0.0009 or less. Lower dielectric dissipation factor at 5 GHz is preferable, and the lower limit value thereof is not particularly limited to a specific one, and may be, for example, 0.0001 or more. In the present specification, the dielectric dissipation factor of the resin composition is calculated as an average value of dielectric dissipation factors measured, using a sample having a film shape (or a sheet shape) as a measurement target, in one in-plane direction (X direction) and an in-plane direction (Y direction) perpendicular to the X direction. Specifically, the dielectric dissipation factor of the resin composition is a value measured by the method described in Examples below. In a case where the target is not in a film shape, the target can be formed into a film shape to prepare a sample (e.g., hot pressing, etc.), thereby allowing measurement of the dielectric dissipation factor of the resin composition.

In the resin composition, the percent decrease of the complex viscosity η* may be preferably 19% or less, more preferably 18% or less, further preferably 15% or less, and further more preferably 10% or less. The lower limit of the percent decrease of the complex viscosity η* is not particularly limited to a specific one, and may be, for example, 0.1% or more, and 0.2% or more. In the present specification, the percent decrease of the complex viscosity η* is a value measured by the following operation performed using a rotational rheometer in a parallel plate measurement where a plate diameter is 25 mm and a gap distance is 0.9 mm, under the following conditions: a measurement temperature of Tm₁+20° C., in which Tm₁ denotes an endothermic peak temperature attributed to the thermoplastic liquid crystal polymer contained in the resin composition; a strain of 3.0%; a soak time during each of measurements at frequencies of 1 rad/s and 100 rad/s of 0.0 seconds; and a sampling interval during measurement at the frequency of 100 rad/s of 5.0 s/pt. That is, first, a preheating is performed for 5 minutes after the temperature in the device reaches the above measurement temperature, and then, the operation is performed at the frequency of 1 rad/s for 12 minutes, and subsequently, the frequency is changed to 100 rad/s. Then, a complex viscosity η*_{X} is measured as a value at a point of the frequency change, and a complex viscosity η*_{Y} is measured as a value at a point 7 minutes after the point of the frequency change. The percent decrease of the complex viscosity η* is a value calculated from the following formula: (η*_{X}−η*_{Y})/η*_{X}×100.

The endothermic peak temperature Tm₁ denotes a temperature at an endothermic peak attributed to the thermoplastic liquid crystal polymer contained in the resin composition, which is observed when the temperature is increased from 25° C. to 400° C. at a rate of 20° C./min in differential scanning calorimetry of the resin composition. The “temperature at endothermic peak” is a temperature at a top of the endothermic peak. In a case where a plurality of endothermic peaks attributed to the thermoplastic liquid crystal polymers are observed in measurement of a sample, the endothermic peak temperature attributed to the thermoplastic liquid crystal polymer having the largest weight ratio in the sample is defined as Tm₁. In a case where a plurality of endothermic peaks attributed to the thermoplastic liquid crystal polymers are observed in measurement of a sample and the weight ratios of a plurality of thermoplastic liquid crystal polymers corresponding to the respective endothermic peaks are equal, the lowest endothermic peak temperature is defined as Tm₁. For example, the endothermic peak temperature Tm₁ may be in a range of from 260 to 370° C., preferably in a range of from 280 to 360° C., and more preferably in a range of from 290 to 350° C.

From the viewpoint of melt-formability, the resin composition may have a melt viscosity of 30 to 120 Pa·s, where the melt viscosity is measured using a capillary rheometer under the following conditions: a capillary diameter of 1.0 mm; a capillary length of 20 mm; a temperature of the endothermic peak temperature Tm₁+20° C.; a shear rate of 1000 sec⁻¹; and a preheating time of 5 minutes. The melt viscosity of the resin composition may be preferably 35 to 80 Pa·s, more preferably 40 to 70 Pa·s, and further preferably 42 to 65 Pa·s. If this value is too high, a molten resin may stagnate during a melt-forming process, and on the other hand, if it is too low, sufficient melt tension may fail to be exerted during film formation. The melt viscosity is a value measured by the method described in Examples below.

From the viewpoint of melt-formability, the resin composition may have a ratio Y/X of 1.30 or less, where X denotes a melt viscosity (Pa·s) measured using a capillary rheometer under the following conditions: a capillary diameter of 1.0 mm; a capillary length of 20 mm; a temperature of the endothermic peak temperature Tm₁+20° C.; a shear rate of 1000 sec⁻¹; and a preheating time of 5 minutes, and Y denotes a melt viscosity (Pa·s) subsequently measured under conditions of the same temperature and shear rate after the resin composition is allowed to stand at the same temperature in a barrel of the capillary rheometer for 30 minutes. If the ratio Y/X of the melt viscosity is too high, the resin composition is thickened when heated, and therefore, molten resin composition tends to stagnate during melt-formation, and have poor melt-formability. The ratio Y/X of the melt viscosity of the resin composition may be preferably 1.25 or less and more preferably 1.20 or less. The lower limit of the ratio Y/X of the melt viscosity of the resin composition is not particularly limited to a specific one, and may be, for example, 1.00 or more.

The resin composition may have a melt tension of 0.002 N or more, where the melt tension is measured using a capillary rheometer by taking up the resin composition at a speed of 30 m/min, with a distance from a capillary outlet to a center position of a tension pulley set at 200 mm, under the following conditions: a capillary diameter of 1.0 mm; a capillary length of 20 mm; a temperature of the endothermic peak temperature Tm₁+20° C.; a shear rate of 1000 sec⁻¹; and a preheating time of 5 minutes. If the melt tension is too low, it may lead to film-forming troubles in melt-formation, such as draw resonance occurred during film formation using a T die, or unstable bubble during inflation formation. The melt tension of the resin composition may be preferably 0.003 N or more, and more preferably 0.004 Nor more. The upper limit of the melt tension of the resin composition is not particularly limited to a specific one, and may be, for example, 0.01 N or less.

From the viewpoint of heat resistance, the resin composition may have a difference Tm₁−Tm₆ of 12° C. or less, where Tm₁ denotes an endothermic peak temperature during a first heating run, and Tm₆ denotes an endothermic peak temperature during a sixth heating run, as measured using a differential scanning calorimeter. These endothermic peak temperatures are measured by repeating a heating and cooling cycle 6 times in differential scanning calorimetry of the resin composition under a heating condition in which a temperature is increased from 25° C. to 400° C. at a rate of 20° C./min and is maintained for 2 minutes after the temperature reaches 400° C., and a cooling condition in which after the heating condition, the temperature is decreased from 400° C. to 25° C. at a rate of 20° C./min and is maintained for 2 minutes after the temperature reaches 25° C. In the measurement, the temperature of an endothermic peak during the first heating run is defined as Tm₁ (° C.), and the temperature of an endothermic peak during the sixth heating run is defined as Tm₆ (° C.). The difference Tm₁−Tm₆ of the endothermic peak temperatures is an index indicating how much the endothermic peak temperature, which means the melting point of the thermoplastic liquid crystal polymer, has decreased due to a thermal history caused by the heating and cooling cycle. If this value is too high, it is predicted that transesterification has occurred in the thermoplastic liquid crystal polymer by heating, and there is a tendency that heat resistance of the thermoplastic liquid crystal polymer is deteriorated due to the thermal history. The difference Tm₁−Tm₆ of the endothermic peak temperatures may be preferably 10° C. or less, more preferably 9° C. or less, and further preferably 8° C. or less.

The resin composition is not limited to a specific one as long as the dielectric dissipation factor and the percent decrease of the complex viscosity rf are in specific ranges, and for example, may contain particulate materials. In the present specification, the particulate materials refer to a component that is dispersed in and incompatible with the matrix, at room temperature, of the thermoplastic liquid crystal polymer having a predetermined composition (the combination of repeating units and the contents thereof) contained as a main component in the resin composition. The shapes of the particulate materials is not particularly limited to a specific one, and the particulate materials may be present in any particle shape, such as a spherical shape, a cylindrical shape, a honeycomb shape, a fiber shape, or an irregular shape. The particulate materials can be identified by confirming to be dispersed in the matrix of the thermoplastic liquid crystal polymer contained as the main component. For example, the particulate materials may have an average particle diameter of 50 μm or less, preferably 30 μm or less, and more preferably 10 μm or less. The lower limit of the average particle diameter is not particularly limited to a specific one, and may be, for example, 0.01 μm or more. The average particle diameter of the particulate materials is calculated as an average value of maximum diameters of the particulate materials dispersed in the matrix, according to an image analysis method using an electron microscope (e.g., SEM). The particulate materials can correspond to not only an additive material described later but also a particulate thermoplastic liquid crystal polymer having a composition different from that of the thermoplastic liquid crystal polymer contained as a main component. In the present specification, the “main component” refers to a component contained in the largest amount in the resin composition. Even when a thermoplastic liquid crystal polymer is contained as the particulate materials, the repeating units and their contents of the thermoplastic liquid crystal polymer in the resin composition are defined as all repeating units of all the thermoplastic liquid crystal polymers contained in the resin composition and the average value of the contents, as described above, without discriminating between the main component and the particulate materials.

The resin composition is not limited to a specific one as long as the dielectric dissipation factor and the percent decrease of the complex viscosity η* are in specific ranges, and for example, may contain an additive material. The additive material is a component other than the thermoplastic liquid crystal polymer, and may be at least one selected from the group consisting of a thermoplastic resin, a thermosetting resin, an inorganic compound, and a liquid crystalline oligomer. The additive material is preferably at least one selected from the group consisting of the thermoplastic resin and the inorganic compound.

The thermoplastic resin is not particularly limited to a specific one as long as the thermoplastic resin is a thermoplastic resin other than the thermoplastic liquid crystal polymer described above. Examples of the thermoplastic resin include an amorphous polyarylate-based resin, a polyphenylene ether-based resin, a polyphenylene sulfide-based resin, a polyetherimide-based resin, a polyether sulfone-based resin, a polyether ether ketone-based resin, a polycarbonate-based resin, a fluorine-based resin, and the like. The amorphous polyarylate-based resin refers to an amorphous aromatic polyester resulting from polycondensation of a dihydric phenol and an aromatic dicarboxylic acid, and examples of the amorphous polyarylate-based resin include a copolymer of bisphenol A, and terephthalic acid and isophthalic acid, and the like. The fluorine-based resin refers to a polymer including a fluorine atom in the molecular chain, and examples thereof include polytetrafluoroethylene (PTFE), polyvinylidene fluoride (PVDF), a copolymer (PFA) of tetrafluoroethylene and perfluoroalkoxyethylene, and the like. Among these thermoplastic resins, the amorphous polyarylate-based resin, the polyphenylene ether-based resin, and the fluorine-based resin are preferable.

Examples of the thermosetting resin include an epoxy-based resin, an unsaturated polyester-based resin, a thermosetting polyimide-based resin, a bismaleimide-based resin, a phenol-based resin, a melamine-based resin, a thermosetting polyurethane-based resin, and the like.

Examples of the inorganic compound include silica (silicon oxide), alumina (aluminum oxide), titanium oxide, zirconium oxide, silicon carbide, aluminum nitride, boron nitride, barium titanate, glass, mica, talc, and the like. Among these inorganic compounds, the inorganic compound may be preferably at least one selected from the group consisting of silica and titanium oxide, and more preferably silica.

Preferably, the inorganic compound is contained as inorganic particles. The inorganic particles may have a median diameter of 0.01 to 10 μm, preferably 0.03 to 5 μm, and more preferably 0.05 to 1 μm. In the present specification, the median diameter of inorganic particles indicates a particle diameter at which the cumulative value reaches 50% in the particle size distribution measured by a laser diffraction-scattering method.

The resin composition may contain two or more types of inorganic particles having different median diameters from each other. The inorganic particles having different median diameters from each other may be inorganic particles of the same kind having different median diameters from each other, or may be inorganic particles of different kinds having different median diameters from each other.

The liquid crystalline oligomer refers to an oligomer not higher than a decamer having repeating units selected from the various repeating units exemplified with respect to the thermoplastic liquid crystal polymer described above, and can be produced by a known polymerization method such as polycondensation of a raw material compound (monomer) described above. The term “not higher than a decamer” means that the number of repeating units in one molecule is 10 or less in total.

The resin composition may contain two or more types of the additive materials. Two or more additive materials having different chemical structures from each other can be used. For example, from each of the thermoplastic resin, the thermosetting resin, the inorganic compound, or the liquid crystalline oligomer, two or more additive materials may be used (e.g., two or more thermoplastic resins, two or more inorganic compounds, etc.). Alternatively, at least two additive materials selected from the group consisting of the thermoplastic resin, the thermosetting resin, the inorganic compound, and the liquid crystalline oligomer may be used (e.g., one or more thermoplastic resins and one or more inorganic compounds, or one or more thermoplastic resins and one or more thermosetting resins, etc.).

In the resin composition, the dielectric dissipation factor and the percent decrease of the complex viscosity η* can be adjusted by the additive material to be used and contents thereof. For example, a weight ratio (thermoplastic liquid crystal polymer/additive material) of the thermoplastic liquid crystal polymer to the additive material may be in a range of from 63.0/37.0 to 94.9/5.1, preferably from 66.0/34.0 to 94.5/5.5, and more preferably from 72.0/28.0 to 93.0/7.0. In the present specification, when the resin composition contains two or more types of the additive materials, the weight ratio is calculated from a total amount of all the additive materials.

In one embodiment, the resin composition may contain the thermoplastic liquid crystal polymer and the inorganic compound. As the inorganic compound, the above-described inorganic compound can be used, and the inorganic particles are preferably used. For example, the inorganic compound may be at least one selected from the group consisting of silica particles and titanium oxide particles. As these inorganic particles, two or more inorganic particles having different median diameters from each other may be used, and for example, the resin composition may contain silica particles and titanium oxide particles having different median diameters from each other, or may contain two or more types of silica particles having different median diameters from each other.

In another embodiment, the resin composition may contain the thermoplastic liquid crystal polymer and the thermoplastic resin. As the thermoplastic resin, the above-described thermoplastic resin can be used, and at least one selected from the group consisting of an amorphous polyarylate-based resin, a polyphenylene ether-based resin, and a fluorine-based resin is preferably used.

The resin composition may contain the thermoplastic resin as thermoplastic resin particles, and for example, may contain fluorine-based resin particles.

In another embodiment, the resin composition may contain the thermoplastic liquid crystal polymer, the thermoplastic resin, and the inorganic compound. For example, the resin composition may contain at least one selected from the group consisting of an amorphous polyarylate-based resin and a polyphenylene ether-based resin as the thermoplastic resin, and silica as the inorganic compound.

The resin composition may contain two or more types of thermoplastic liquid crystal polymers having different compositions from each other. For example, the resin composition may contain, as a component other than the thermoplastic liquid crystal polymer as the main component, the thermoplastic liquid crystal polymer as the particulate materials.

When the resin composition contains the thermoplastic liquid crystal polymer and the inorganic compound, a weight ratio (thermoplastic liquid crystal polymer/inorganic compound) of the thermoplastic liquid crystal polymer to the inorganic compound may be in a range of from 66.0/34.0 to 96.0/4.0, preferably from 80.0/20.0 to 94.9/5.1, and more preferably from 90.0/10.0 to 94.0/6.0.

A content of the inorganic compound in the resin composition may be 0 to 30 wt %, preferably 1 to 15 wt %, and more preferably 4.5 to 9.5 wt %, based on a solid weight content in the resin composition.

When the resin composition contains the thermoplastic liquid crystal polymer and the thermoplastic resin, a weight ratio (thermoplastic liquid crystal polymer/thermoplastic resin) of the thermoplastic liquid crystal polymer to the thermoplastic resin may be in a range of from 60.0/40.0 to 96.0/4.0, preferably from 63.0/37.0 to 94.9/5.1, and more preferably from 65.0/35.0 to 94.0/6.0.

A content of the thermoplastic resin in the resin composition may be 0 to 37 wt %, preferably 3 to 30 wt %, and more preferably 5 to 28 wt %, based on the solid weight content in the resin composition.

A total content of the inorganic compound and the thermoplastic resin in the resin composition may be 4 to 37 wt %, preferably 5 to 30 wt %, and more preferably 6 to 20 wt %, based on the solid weight content in the resin composition.

### [Method for Producing Resin Composition]

The resin composition can be produced by mixing the above-described thermoplastic liquid crystal polymer and additive material by a known method. The resin composition may be produced by mixing two or more types of thermoplastic liquid crystal polymers having different compositions from each other. The resin composition may be produced by mixing thermoplastic liquid crystal polymers obtained by adjusting a degree of polymerization through solid-phase polymerization after polymerization in the melt phase.

The resin composition may be produced by melt-kneading raw materials of the above-described thermoplastic liquid crystal polymer, additive material, and the like using an extruder. The extruder to be used in melt-kneading is not particularly limited to a specific one, and a single-screw extruder, a twin-screw extruder, a multi-screw extruder, and the like can be used. Among these, the twin-screw extruder is preferable from the viewpoint of uniformly dispersing accessory components (e.g., additive material) in the resin composition.

From the viewpoint of uniformly mixing the raw material components, L/D of the extruder is preferably 10 to 100, more preferably 15 to 80, and further preferably 20 to 60. When L/D is 10 or more, the resin composition having an excellent kneaded state is easily obtained. On the other hand, when L/D is 100 or less, shear heating during kneading can be reduced so as to prevent thermal decomposition of each component in the resin composition. It should be noted that L [unit: mm] denotes a length of a cylinder of the extruder, and D [unit: mm] denotes an inner diameter of the cylinder of the extruder.

Preferably, the extruder includes one or more open vent parts. When such an extruder is used, decomposition products and volatile components can be suctioned from the open vent part so as to improve the quality of the obtained resin composition. In order to suction the decomposition products and the like from the open vent part, for example, the open vent part is preferably set to a reduced pressure state. When the pressure is reduced, the pressure is preferably 0.1 to 90 kPa, more preferably 0.3 to 80 kPa, further preferably 0.5 to 50 kPa, and particularly preferably 0.7 to 10 kPa. When the pressure at the open vent part is 90 kPa or less, residual amounts of the decomposition products and volatile components can be reduced. On the other hand, when the pressure at the open vent part is 0.1 kPa or more, productivity of the resin composition can be improved.

To the extruder, a known die can be connected according to the desired shape of the resin composition. For example, in a case where a strand die is connected to the extruder, the resin composition extruded from the strand die is cut into a desired length to obtain the resin composition in a particulate shape or a columnar shape.

The method for feeding the raw materials of the resin composition to the extruder is not particularly limited to a specific one, and all raw materials may be fed together from a weigh feeder to a raw material feed hopper, or each of the raw materials may be fed or some of the raw materials may be fed together to the raw material feed hopper by using two or more weigh feeders. When some of or all of the raw materials are mixed to produce a preliminary mixture, the producing method is not particularly limited to a specific one, and for example, the raw materials can be mixed using a known mixer such as a tumbler mixer or a Henschel mixer.

Examples of the screw configuration of the extruder include screws having: a conveying section which has a full flight screw segment for conveying the raw materials and the kneaded product of the resin composition; and a kneading section which has a kneading disc (with forward conveying, neutral, and reverse conveying, etc.) for kneading the raw materials of the resin composition, and a screw segment (screw segment in which the helical direction is reverse; reverse flight screw segment) for reversing in the conveying direction of the molten resin. From the viewpoint of uniformly dispersing the accessory components (e.g., additive material) in the resin composition, the screw preferably has one or two or more kneading sections. In order to avoid increase in the resin pressure at the twin-screw extruder head part, the conveying section is preferably provided rearward of the kneading section for conveying the kneaded product of the resin composition to a die part, etc.

From the viewpoint of preventing deterioration of the resin composition, the resin composition may be melt-kneaded with an inert gas supplied into the extruder.

In order to remove foreign substances, a polymer filter may be provided rearward of the extruder. Examples of the polymer filter include a candle-type polymer filter, a leaf disk-type polymer filter, and the like.

### [Film]

The above-described resin composition can be suitably used for forming a film. The film can be produced by extruding the resin composition. Although any extrusion methods may be used, well-known methods such as a T-die method and an inflation method are industrially advantageous. In particular, in the inflation method, stress can be applied not only in a machine direction of the film (hereinafter, abbreviated as an MD direction), but also in a transverse direction (hereinafter, abbreviated as a TD direction) perpendicular to the MD direction, which allows the film to be uniformly stretched in both the MD and TD directions. Accordingly, it is possible to obtain a film having controlled properties such as molecular orientation and dielectric characteristics in both the MD and TD directions.

If necessary, the extruded film may be subjected to further stretching. The stretching method itself is known, and either biaxial stretching or uniaxial stretching may be employed. From the viewpoint of easy control of molecular orientation, biaxial stretching is preferable. The stretching may be carried out using a known machine such as a uniaxial stretching machine, a simultaneous biaxial stretching machine, and a sequential biaxial stretching machine.

The extrusion molding may be accompanied by a stretching treatment in order to control the orientation. For example, in the extrusion molding using a T-die method, a film may be formed by stretching a molten polymer sheet extruded from a T-die in the MD direction and the TD direction of the thermoplastic liquid crystal polymer film at the same time, alternatively, a film may be formed by stretching a molten polymer sheet extruded from a T-die in sequence, first in the MD direction and then the TD direction.

Also, in the extrusion molding using an inflation method, a film may be formed by drawing a tubular sheet melt-extruded from an annular die in a predetermined draw ratio (corresponding to a stretching ratio in the MD direction) and a predetermined blow ratio (corresponding to a stretching ratio in the TD direction).

The film obtained in this manner includes the above-described resin composition. The above-described resin composition has a low percent decrease of the complex viscosity η* in a specific range, and thus, has high stability in the liquid crystal domain under shear so as to allow formation of a film with reduced thickness unevenness. For example, the film may have a coefficient of variation of thickness in a film width direction of 1.90% or less, preferably 1.80% or less, more preferably 1.75% or less, further preferably 1.70% or less, further more preferably 1.40% or less, and particularly preferably 1.30% or less, as measured using a continuous thickness gauge. In the present specification, the coefficient of variation of thickness is calculated from a formula of the thickness standard deviation/thickness average value×100 on the basis of measurement value data of thickness in the film width direction, and is a value measured by the method described in Examples below.

The film can have an adjusted thickness depending on the application, and may be selected from a wide range of, for example, 1 to 500 μm. In consideration of the application as a material for an insulating layer for a circuit board, the thickness of the film may be preferably 5 to 200 μm and more preferably 10 to 150 μm.

The film may have a melting point (Tm) in a range of from 260 to 370° C., preferably in a range of from 280 to 360° C., and more preferably in a range of from 285 to 350° C. The melting point of the film may be measured by subjecting a film sample to temperature increase from 25° C. at a rate of 20° C./min to determine a temperature at an endothermic peak attributed to the thermoplastic liquid crystal polymer, which is observed during the temperature increase, as the melting point Tm of the film.

### [Metal-Clad Laminate]

The above-described film can be used for a metal-clad laminate including the film and a metal layer bonded to at least one surface of the film. The metal-clad laminate may be a single-sided metal-clad laminate having a metal layer on one surface of the film, or a double-sided metal-clad laminate having metal layers on both surfaces of the film. In the metal-clad laminate, the film and the metal layer may be laminated via an adhesion layer (e.g., an adhesive). On the other hand, from the viewpoint of reducing the thickness for using as a circuit board producing material, it is preferable that in the metal-clad laminate, the film and the metal layer are directly laminated to each other without an adhesion layer therebetween.

The metal-clad laminate may be produced by thermocompression bonding a metal foil to the above-described film to form the metal layer, or by sputtering, vapor deposition, electroless plating, or the like to the above-described film to form the metal layer, or may be produced by casting the resin composition onto a metal foil.

The metal for forming the metal layer is not particularly limited to a specific one, and for example, may be gold, silver, copper, iron, tin, nickel, aluminum, chromium, alloy of these metals, or the like. In these metals, another kind of metal may be contained at a proportion of 2000 mass ppm or less, and/or inevitable impurities may be present.

When the metal foil is used as the metal layer, the metal foil may be a metal foil formed from the above metal, for example, and from the viewpoint of conductivity, handleability, cost, and the like, a copper foil or a stainless steel foil is preferable. As the copper foil, those manufactured by a rolling process or an electrolytic process can be used. The metal foil may be subjected to usually-performed surface treatment such as roughening treatment, as long as high frequency characteristics of the metal-clad laminate of the present invention are not impaired.

In the process of sputtering or vapor deposition, a metal part is brought into contact with and is adhered to the film by sputtering or vapor depositing a metal. Sputtering and vapor deposition are well-known methods in the field of circuit board manufacture. Examples of the metal for sputtering or vapor deposition include copper, aluminum, gold, tin, chromium, and the like.

In the process of electroless plating, a metal is deposited from a solution containing metal ions and is adhered onto the film. Electroless plating is a well-known methods in the field of manufacturing of plated product made of non-conductive materials (such as plastics and ceramics). Examples of the metal for electroless plating include copper, nickel, cobalt, gold, tin, chromium, and the like.

The metal-clad laminate can be effectively used as a component, such as a circuit board material, which is used in the electricity and electronics fields, office equipment and high precision machine fields, power semiconductor fields, and the like.

### [Circuit Board]

The above-described resin composition can be used for a circuit board at least including an insulating layer containing the resin composition, and a conductor layer. For example, the circuit board can be produced by forming a conductor pattern on a surface of the above-described film. The circuit board can be produced by wiring-circuit processing of the metal layer of the above-described metal-clad laminate. As the circuit processing method, a known method can be used. For example, the metal layer on the film may be etched to form a circuit by a subtractive method.

The conductor layer is formed from, for example, a metal at least having conductivity, and a circuit is formed on the conductor layer using a known method for processing a circuit. A conductor for forming the conductor layer can be various metals having conductivity, such as gold, silver, copper, iron, tin, nickel, aluminum, chromium, or alloy of these metals.

The circuit board can be used as various high frequency circuit boards. The circuit board may be a circuit board (or a semiconductor element-mounted board) having a semiconductor element (e.g., IC chip) mounted thereon. Since the circuit board has the dielectric dissipation factor that is controlled to be low, it may be used for various transmission lines, for example, known or conventional transmission lines such as coaxial lines, strip lines, microstrip lines, coplanar lines, and parallel lines, or may be used for antennas (e.g., antenna for microwave or millimeter wave). The circuit board may also be used for an antenna device having an antenna and a transmission line integrated. For example, the circuit board may be used for various sensors, in particular, vehicular radars.

Examples of the antenna include antennas using millimeter waves or microwaves, such as a waveguide slot antenna, a horn antenna, a lens antenna, a printed antenna, a triplate antenna, a microstrip antenna, and a patch antenna.

### EXAMPLES

Hereinafter, the present invention will be described in more detail with reference to the Examples. However, the present invention is not limited by the Examples whatsoever. In the Examples and Comparative Examples below, various properties were measured by the following methods.

### [Endothermic Peak Temperature]

Using a differential scanning calorimeter (“DSC Q2000” manufactured by TA Instruments Japan Inc.), 5.0 mg of the resin composition was put into a sample container, and a heating and cooling cycle was repeated 6 times under the following heating and cooling conditions. In the measurement, the temperature at an endothermic peak attributed to the thermoplastic liquid crystal polymer during a first heating run was defined as Tm₁ (° C.), and the temperature at an endothermic peak attributed to the thermoplastic liquid crystal polymer during a sixth heating run was defined as Tm₆ (° C.). A difference Tm₁−Tm₆ (° C.) was calculated from those values.

### (Heating and Cooling Conditions)

Heating condition: a temperature is increased from 25° C. to 400° C. at a rate of 20° C./min, and is maintained for 2 minutes after the temperature reaches 400° C.
Cooling condition: a temperature is decreased from 400° C. to 25° C. at a rate of 20° C./min, and is maintained for 2 minutes after the temperature reaches 25° C.

### [Melting Point of Film]

Using a differential scanning calorimeter (“DSC Q2000” manufactured by TA Instruments Japan Inc.), a sample of a predetermined size was taken from a film obtained in each of Examples and Comparative Examples, and was put into a sample container, and a temperature at an endothermic peak observed when the temperature was increased from 25° C. to 400° C. at a rate of 20° C./min was determined as the melting point Tm of the film.

### [Dielectric Dissipation Factor]

A film obtained in each of Examples and Comparative Examples was cut in the MD direction to obtain a sample piece having a length of 8 cm and a width of 2 mm. Another film obtained in the same manner was cut in the TD direction in the same manner to obtain a sample piece having a length of 8 cm and a width of 2 mm. Measurement for dielectric dissipation factor was performed by a perturbation method using a cavity resonator at a frequency of 5 GHz. A cavity resonator (produced by Kanto Electronics Application & Development Inc.) at 5 GHz was connected to a network analyzer (“E8362B” produced by Agilent Technologies, Inc.), and the above sample piece was inserted into the cavity resonator to perform the measurement at 25° C. The dielectric dissipation factors in the MD direction and the TD direction were measured, and an average value thereof was calculated as the dielectric dissipation factor.

### [Percent Decrease of Complex Viscosity η*]

### (Sample Preparation)

A resin composition obtained in each of Examples and Comparative Examples was subjected to hot pressing at a pressure condition of 100 kg/cm² under a temperature condition of Tm₁+15 to Tm₁+30° C. (Tm₁ is the above-measured endothermic peak temperature attributed to the thermoplastic liquid crystal polymer during the first heating run), to obtain a 10 cm-square sheet having a thickness of 0.9 mm, a vertical length of 10 cm, and a horizontal length of 10 cm. Then, the resultant sheet was punched into a disc shape having a diameter of 25 mm, to obtain a measurement sample.

### (Measurement Method)

Using a rotational rheometer (“ARES-G2” manufactured by TA Instruments Japan Inc.), the measurement sample was set to a parallel plate having a plate diameter of 25 mm, and measurement was performed by the following operation under the following conditions: a gap distance of 0.9 mm; a measurement temperature of Tm₁+20° C., in which Tm₁ was the endothermic peak temperature of the resin composition determined above; a strain of 3.0%; a soak time during each of measurements at frequencies of 1 rad/s and 100 rad/s of 0.0 seconds; and a sampling interval during measurement at the frequency of 100 rad/s of 5.0 s/pt. First, a preheating was performed for 5 minutes after the temperature in the device reached the above measurement temperature. Next, the operation was performed at the frequency of 1 rad/s for 12 minutes, and then, the frequency is changed to 100 rad/s, and the operation was maintained at the frequency of 100 rad/s. A complex viscosity at a point of the frequency change was defined as η*_{X}, and a complex viscosity at a point 7 minutes after the point of the frequency change was defined as η*_{Y}. The percent decrease (%) of the complex viscosity η* was calculated from the following formula: (η*_{X}−η*_{Y})/η*_{X}×100.

### [Melt Viscosity]

A resin composition obtained in each of Examples and Comparative Examples was dried for 16 hours at 140° C. under a degree of vacuum of 1.4 kPa using a vacuum drier. Using a capillary rheometer (“CAPILOGRAPH (registered trademark) F-2” manufactured by Toyo Seiki Seisaku-sho, Ltd.; a barrel diameter of 15 mm), the resin composition was put into a barrel, and measurement was performed by the following operation under the following conditions: a capillary diameter of 1.0 mm; a capillary length of 20 mm; and a measurement temperature of Tm₁+20° C., in which Tm₁ was the endothermic peak temperature of the resin composition determined above. A preheating was performed in the barrel for 5 minutes after the temperature in the barrel reached the above measurement temperature, and then, a melt viscosity was measured under the conditions of the above measurement temperature and a shear rate of 1000 sec⁻¹, and this melt viscosity was defined as X (Pa·s).

After the above melt viscosity X was measured, a piston was stopped, the molten resin was allowed to stand for 30 minutes in the barrel, and then, a melt viscosity was measured under the conditions of the same temperature and the same shear rate, and this melt viscosity was defined as Y (Pa·s). The ratio Y/X of the melt viscosity was calculated from these values.

### [Melt Tension]

A resin composition obtained in each of Examples and Comparative Examples was dried for 16 hours at 140° C. under a degree of vacuum of 1.4 kPa using a vacuum drier. Using a capillary rheometer (“CAPILOGRAPH (registered trademark) F-2” manufactured by Toyo Seiki Seisaku-sho, Ltd.; a barrel diameter of 15 mm), the resin composition was put into a barrel, and measurement was performed by the following operation under the following conditions: a capillary diameter of 1.0 mm; a capillary length of 20 mm; a measurement temperature of Tm₁+20° C., in which Tm₁ was the endothermic peak temperature of the resin composition determined above; and a distance from a capillary outlet to a center position of a tension pulley of 200 mm. A preheating was performed in the barrel for 5 minutes after the temperature in the barrel reached the above measurement temperature, and then, a melt tension was measured when the resin composition was taken up while the take-up speed was increased from 25 m/min to 50 m/min at an acceleration of 0.02778 m/s² under the conditions of the above measurement temperature and a piston speed of 33.33 mm/min (a shear rate of 1000 sec⁻¹), and the melt tension (N) at the time of taking up at a speed of 30 m/min was identified.

### [Film Thickness]

A film obtained in each of Examples and Comparative Examples was cut into five sample pieces having a TD direction width of 210 mm and an MD direction width of 30 mm. Using a desktop thickness gauge (“RC-1W” manufactured by MAYSUN Co., Ltd.), thickness was measured at an interval of 0.5 mm while feeding each of the above five sample pieces in the TD direction at a feed speed of 60 mm/sec. First, with respect to each sample piece, the average value of the thicknesses measured in the feed direction was determined. Then, the average value of the thicknesses obtained for each of the five sample pieces was used as thickness data, and from the five pieces of thickness data, the average value was calculated as a thickness (μm). In addition, from the five pieces of thickness data, a standard deviation was calculated as a thickness standard deviation (μm), and a coefficient of variation (%) of thickness was calculated from the following formula.

$$Coefficient of variation of thickness = thickness standard deviation / thickness average value \times 100$$

### Reference Example 1

Into a reactor having a stirrer, a torque meter, a nitrogen gas introduction tube, a thermometer, and a reflux condenser, were introduced 1034.99 g of 6-hydroxy-2-naphthoic acid (HNA; 5.5 mol), 83.07 g of terephthalic acid (TPA; 0.5 mol), 378.33 g of 2,6-naphthalenedicarboxylic acid (NDCA; 1.75 mol), 272.52 g of hydroquinone (HQ; 2.475 mol, 0.225 mol used in excess), 1226.87 g of acetic anhydride (11.9 mol), and, as a catalyst, 0.17 g of 1-methylimidazole. The mixture was stirred at room temperature for 15 minutes under a nitrogen atmosphere, and then, the temperature was increased with stirring, and was maintained at 145° C. for 1 hour. Next, the temperature was increased from 145° C. to 310° C. over 3 hours and 30 minutes while by-product acetic acid and unreacted acetic anhydride were evaporated. The temperature was maintained at 310° C. for 3 hours and then was cooled to room temperature, and the mixture was crushed using a crusher, to obtain powder of a thermoplastic liquid crystal polymer.

The obtained powder was heated under a heating atmosphere. The temperature was increased from 25° C. to 250° C. over 1 hour, and then, was increased from 250° C. to 315° C. over 5 hours. Next, the temperature was maintained at 315° C., and solid-phase polymerization was performed until an endothermic peak temperature became 320.5° C. and a melt viscosity at 340.5° C. at a shear rate of 1000 s⁻¹ became 54 Pa·s. Then, the solid-phase-polymerized powder was cooled, and the cooled powder was granulated at 340° C. using a twin-screw kneading extruder, to obtain pellets of a thermoplastic liquid crystal polymer A.

### Reference Example 2

Into a reactor having a stirrer, a torque meter, a nitrogen gas introduction tube, a thermometer, and a reflux condenser, were introduced 20.19 g of 6-hydroxy-2-naphthoic acid (HNA; 107.3 mmol), 7.73 g of 2,6-naphthalenedicarboxylic acid (NDCA; 35.8 mmol), 1.97 g of hydroquinone (HQ; 17.9 mmol), 3.33 g of 4,4′-dihydroxybiphenyl (BP; 17.9 mmol), 20.08 g of acetic anhydride (196.7 mmol), and, as a catalyst, 3.77 mg of potassium acetate. While stirring the mixture under a nitrogen atmosphere, the temperature was increased from room temperature, and was maintained at 160° C. for about 2 hours. Then, the temperature was increased, and was maintained at 280° C. for 0.5 hours, at 320° C. for 1 hour, and at 360° C. for 1 hour. Next, vacuum treatment (100 Pa) was performed until it was confirmed that foaming has stopped (for 30 to 120 minutes), and subsequently the reactor was purged with nitrogen and the mixture was cooled to room temperature, and the mixture was crushed using a crusher, to obtain powder of a thermoplastic liquid crystal polymer. The obtained cooled powder had an endothermic peak temperature of 291.1° C. and a melt viscosity at 311.1° C. at a shear rate of 1000 s⁻¹ of 55 Pa·s. The cooled powder was granulated at 315° C. using a twin-screw kneading extruder, to obtain pellets of a thermoplastic liquid crystal polymer B.

### Reference Example 3

Into a reactor having a stirrer, a torque meter, a nitrogen gas introduction tube, a thermometer, and a reflux condenser, were introduced 660.5 g of 6-hydroxy-2-naphthoic acid (HNA; 3.51 mol), 248.3 g of terephthalic acid (TPA; 1.49 mol), 14.3 g of hydroquinone (HQ; 0.13 mol), 254.2 g of 4,4′-dihydroxybiphenyl (BP; 1.37 mol), and 1.03-times mol of acetic anhydride with respect to the amount (mol) of hydroxy groups of all monomers. While stirring the mixture under a nitrogen atmosphere, the temperature was increased from room temperature to 150° C. over 1 hour, and was maintained at 150° C. for 1 hour. Next, the temperature was increased to 350° C. over 7 hours while by-product acetic acid was evaporated, and then, the pressure was reduced to 1333 Pa over 90 minutes. At the time point when a predetermined torque was reached, polymerization reaction was stopped, the temperature was cooled to room temperature, and the mixture was crushed using a crusher, to obtain powder of a thermoplastic liquid crystal polymer.

The obtained powder was heated under a heating atmosphere. The temperature was increased from 25° C. to 250° C. over 1 hour, and then, was increased from 250° C. to 325° C. over 2 hours. Next, the temperature was maintained at 325° C., and solid-phase polymerization was performed until an endothermic peak temperature became 340.0° C. and a melt viscosity at 360.0° C. at a shear rate of 1000 s⁻¹ became 55 Pa·s. The cooled powder was granulated at 360° C. using a twin-screw kneading extruder, to obtain pellets of a thermoplastic liquid crystal polymer C.

### Reference Example 4

A thermoplastic liquid crystal polymer (“A920RX” manufactured by Polyplastics Co., Ltd.; HBA/HNA=73/27 (mol)) was subjected to temperature increase from 25° C. to 240° C. over 1 hour. Next, the temperature was maintained at 240° C., and solid-phase polymerization was performed until an endothermic peak temperature became 295.0° C. and a melt viscosity at 315.0° C. at a shear rate of 1000 s⁻¹ became 53 Pa·s. The cooled powder was granulated at 315° C. using a twin-screw kneading extruder, to obtain pellets of a thermoplastic liquid crystal polymer D.

The following additive materials were used.
Silica particle A (“surface treated admafine silica SC2500-SQ” manufactured by ADMATECHS COMPANY LIMITED, median diameter of 0.5 μm)
Silica particle B (manufactured by ADMATECHS COMPANY LIMITED, median diameter of 0.3 μm)
Polyphenylene ether (PPE; “XYRON S201A” manufactured by Asahi Kasei Corporation)
Amorphous polyarylate (PAR; “U-100” manufactured by UNITIKA LTD.)

### Example 1

90.9 wt % of the thermoplastic liquid crystal polymer A obtained in Reference Example 1 and 9.1 wt % of the silica particle A were melt-kneaded at a cylinder set temperature of 330° C. using a twin-screw kneading extruder, to produce a resin composition. The analysis results of the obtained resin composition are shown in Table 7.

The obtained resin composition was melt-extruded from a ring inflation die (die diameter of 46.0 mm, die slit interval of 900 μm) at a draw ratio of 2.0 and a blow ratio of 4.2, to produce a film. The analysis results of the obtained film are shown in Table 7.

### Examples 2 to 9, Comparative Examples 1 to 5

A resin composition and a film were produced in the same manner as that in Example 1 except that each component was used at the weight percentage shown 5 in Table 7. The analysis results of the obtained resin compositions and films are shown in Table 7.

TABLE 7

| | | Ex. 1 | Ex. 2 | Ex. 3 | Ex. 4 | Ex. 5 |
|---|---|---|---|---|---|---|
| Weight content of | | 90.9 | 90.9 | 92.6 | 75.0 | 90.9 |
| thermoplastic liquid crystal polymer | | | | | | |
| in resin composition (wt %) | | | | | | |
| Weight content of | Thermoplastic liquid crystal | 90.9 | 90.9 | 92.6 | 75.0 | 77.3 |
| thermoplastic | polymer A | | | | | |
| liquid crystal | Thermoplastic liquid crystal | | | | | |
| polymer (wt %) | polymer B | | | | | |
| | Thermoplastic liquid crystal | | | | | |
| | polymer C | | | | | |
| | Thermoplastic liquid crystal | | | | | 13.6 |
| | polymer D | | | | | |
| Composition ratio | HBA | | | | | 12.5 |
| of thermoplastic | HNA | 55.0 | 55.0 | 55.0 | 55.0 | 50.3 |
| liquid crystal | TPA | 5.0 | 5.0 | 5.0 | 5.0 | 4.1 |
| polymer (mol %) | NDCA | 17.5 | 17.5 | 17.5 | 17.5 | 14.5 |
| | HQ | 22.5 | 22.5 | 22.5 | 22.5 | 18.6 |
| | BP | | | | | |
| Weight content of additive materials | | 9.1 | 9.1 | 7.4 | 25.0 | 9.1 |
| in resin composition (wt %) | | | | | | |
| Weight content of | Silica particle A | 9.1 | | 4.6 | | 9.1 |
| inorganic particle | Silica particle B | | 9.1 | 2.8 | | |
| (wt %) | | | | | | |
| Weight content of | PAR | | | | | |
| thermoplastic resin | PPE | | | | 25.0 | |
| (wt %) | | | | | | |
| Resin composition | Dielectric dissipation factor | 0.0008 | 0.0010 | 0.0010 | 0.0014 | 0.0011 |
| | Percent decrease of complex | 7.9 | 6.4 | 16.3 | 18.9 | 2.3 |
| | viscosity η* (%) | | | | | |
| | Endothermic peak | 320.7 | 320.6 | 320.5 | 319.9 | 319.3 |
| | temperature Tm₁ (° C.) | | | | | |
| | Difference Tm₁ − Tm₆ | 5.0 | 4.4 | 5.2 | 7.2 | 6.6 |
| | of endothermic peak | | | | | |
| | temperature (° C.) | | | | | |
| | Melt viscosity X (Pa · s) | 42 | 50 | 44 | 57 | 44 |
| | Ratio of melt viscosity Y/X | 1.21 | 1.19 | 1.20 | 1.06 | 1.09 |
| | Melt tension (N) | 0.0030 | 0.0043 | 0.0033 | 0.0079 | 0.0049 |
| Film | Thickness average value | 106.1 | 107.2 | 107.3 | 108.0 | 105.6 |
| | (μm) | | | | | |
| | Thickness standard deviation | 0.97 | 0.75 | 1.42 | 1.45 | 0.69 |
| | (μm) | | | | | |
| | Coefficient of variation of | 0.91 | 0.70 | 1.32 | 1.34 | 0.66 |
| | thickness (%) | | | | | |
| | Melting point Tm (° C.) | 317.0 | 317.2 | 316.8 | 316.0 | 316.3 |

| | | Ex. 6 | Ex. 7 | Ex. 8 | Ex. 9 |
|---|---|---|---|---|---|
| Weight content of | | 94.4 | 88.1 | 90.9 | 90.2 |
| thermoplastic liquid crystal polymer | | | | | |
| in resin composition (wt %) | | | | | |
| Weight content of | Thermoplastic liquid crystal | 80.2 | 73.8 | | 90.2 |
| thermoplastic | polymer A | | | | |
| liquid crystal | Thermoplastic liquid crystal | | | 77.3 | |
| polymer (wt %) | polymer B | | | | |
| | Thermoplastic liquid crystal | | | | |
| | polymer C | | | | |
| | Thermoplastic liquid crystal | 14.2 | 14.3 | 13.6 | |
| | polymer D | | | | |
| Composition ratio | HBA | 12.5 | 13.5 | 13.2 | |
| of thermoplastic | HNA | 50.3 | 49.8 | 54.0 | 55.0 |
| liquid crystal | TPA | 4.1 | 4.1 | | 5.0 |
| polymer (mol %) | NDCA | 14.5 | 14.3 | 16.4 | 17.5 |
| | HQ | 18.6 | 18.3 | 8.2 | 22.5 |
| | BP | | | 8.2 | |
| Weight content of additive materials | | 5.6 | 11.9 | 9.1 | 9.8 |
| in resin composition (wt %) | | | | | |
| Weight content of | Silica particle A | 2.8 | 4.8 | 9.1 | 4.8 |
| inorganic particle | Silica particle B | 2.8 | | | |
| (wt %) | | | | | |
| Weight content of | PAR | | | | 5.0 |
| thermoplastic resin | PPE | | | | |
| (wt %) | | | 7.1 | | |
| Resin composition | Dielectric dissipation factor | 0.0010 | 0.0012 | 0.0010 | 0.0015 |
| | Percent decrease of complex | 19.0 | 12.0 | 0.7 | 19.5 |
| | viscosity η* (%) | | | | |
| | Endothermic peak | 319.2 | 321.4 | 290.1 | 321.5 |
| | temperature Tm₁ (° C.) | | | | |
| | Difference Tm₁ − Tm₆ | 6.1 | 9.0 | 6.3 | 4.1 |
| | of endothermic peak | | | | |
| | temperature (° C.) | | | | |
| | Melt viscosity X (Pa · s) | 50 | 51 | 43 | 47 |
| | Ratio of melt viscosity Y/X | 1.12 | 1.08 | 1.10 | 1.28 |
| | Melt tension (N) | 0.0062 | 0.0055 | 0.0046 | 0.0048 |
| Film | Thickness average value | 108.0 | 106.5 | 106.0 | 108.2 |
| | (μm) | | | | |
| | Thickness standard deviation | 1.55 | 1.16 | 0.62 | 1.85 |
| | (μm) | | | | |
| | Coefficient of variation of | 1.44 | 1.09 | 0.58 | 1.71 |
| | thickness (%) | | | | |
| | Melting point Tm (° C.) | 316.4 | 315.7 | 287.3 | 317.2 |

| | | Comp. | Comp. | Comp. | Comp. | Comp. |
|---|---|---|---|---|---|---|
| | | Ex. 1 | Ex. 2 | Ex. 3 | Ex. 4 | Ex. 5 |
| Weight content of | | 100.0 | 100.0 | 97.0 | 60.0 | 95.0 |
| thermoplastic liquid crystal polymer | | | | | | |
| in resin composition (wt %) | | | | | | |
| Weight content of | Thermoplastic liquid crystal | 100.0 | | 97.0 | 60.0 | |
| thermoplastic | polymer A | | | | | |
| liquid crystal | Thermoplastic liquid crystal | | 100.0 | | | |
| polymer (wt %) | polymer B | | | | | |
| | Thermoplastic liquid crystal | | | | | 95.0 |
| | polymer C | | | | | |
| | Thermoplastic liquid crystal | | | | | |
| | polymer D | | | | | |
| Composition ratio | HBA | | | | | |
| of thermoplastic | HNA | 55.0 | 60.0 | 55.0 | 55.0 | 54.0 |
| liquid crystal | TPA | 5.0 | | 5.0 | 5.0 | 23.0 |
| polymer (mol %) | NDCA | 17.5 | 20.0 | 17.5 | 17.5 | |
| | HQ | 22.5 | 10.0 | 22.5 | 22.5 | 2.0 |
| | BP | | 10.0 | | | 21.0 |
| Weight content of additive materials | | 0.0 | 0.0 | 3.0 | 40.0 | 5.0 |
| in resin composition (wt %) | | | | | | |
| Weight content of | Silica particle A | | | 3.0 | 40.0 | |
| inorganic particle | Silica particle B | | | | | |
| (wt %) | | | | | | |
| Weight content of | PAR | | | | | 5.0 |
| thermoplastic resin | PPE | | | | | |
| (wt %) | | | | | | |
| Resin composition | Dielectric dissipation factor | 0.0008 | 0.0007 | 0.0009 | 0.0021 | 0.0010 |
| | Percent decrease of complex | 45.2 | 33.6 | 31.0 | 0.1 | 31.2 |
| | viscosity η* (%) | | | | | |
| | Endothermic peak | 320.5 | 291.1 | 320.7 | 321.2 | 339.0 |
| | temperature Tm₁ (° C.) | | | | | |
| | Difference Tm₁ − Tm₆ | 3.4 | 3.1 | 4.3 | 5.8 | 5.3 |
| | of endothermic peak | | | | | |
| | temperature (° C.) | | | | | |
| | Melt viscosity X (Pa · s) | 54 | 55 | 50 | 52 | 57 |
| | Ratio of melt viscosity Y/X | 1.27 | 1.24 | 1.22 | 1.05 | 1.26 |
| | Melt tension (N) | 0.0071 | 0.0066 | 0.0061 | 0.001 | 0.0071 |
| Film | Thickness average value | 109.2 | 108.9 | 108.9 | 106.0 | 108.7 |
| | (μm) | | | | | |
| | Thickness standard deviation | 2.75 | 2.20 | 2.10 | 0.58 | 2.15 |
| | (μm) | | | | | |
| | Coefficient of variation of | 2.52 | 2.02 | 1.93 | 0.55 | 1.98 |
| | thickness (%) | | | | | |
| | Melting point Tm (° C.) | 316.0 | 287.5 | 316.1 | 316.5 | 335.1 |

As shown in Table 7, since the resin compositions of Examples 1 to 9 has the dielectric dissipation factor at 5 GHz and the percent decrease of the complex viscosity η* in specific ranges, the films obtained by forming such resin compositions have the lower coefficient of variation of thickness.

On the other hand, in Comparative Examples 1 and 2, the dielectric dissipation factor at 5 GHz of the thermoplastic liquid crystal polymer is low, but the percent decrease of the complex viscosity η* is high. Therefore, the films obtained by forming such thermoplastic liquid crystal polymers have the higher coefficient of variation of thickness, and have film thickness unevenness as an appearance defect.

In the resin compositions of Comparative Examples 3 and 5, the dielectric dissipation factor at 5 GHz is low, but the percent decrease of the complex viscosity η* is high. Therefore, the films obtained by forming such resin compositions have the higher coefficient of variation of thickness, and have film thickness unevenness as an appearance defect.

In the resin composition of Comparative Example 4, the percent decrease of the complex viscosity 9* is low, and thus, the film obtained by forming this resin composition had the lower coefficient of variation of thickness. However, since the dielectric dissipation factor at 5 GHz is high, dielectric characteristics in high frequency regions required by various circuit boards are not sufficient.

### INDUSTRIAL APPLICABILITY

The resin composition of the present invention allows formation of a film having a low dielectric dissipation factor in high frequency bands, as well as having reduced thickness unevenness. Therefore, the film obtained by forming the resin composition can be suitably used as a circuit board material for high frequency in the electricity and electronics fields, office equipment and high precision machine fields, power semiconductor fields, and the like.

As described above, the present invention has been described as to the preferred embodiments thereof, but one skilled in the art would easily make various changes or modifications in view of the present description, without departing from the spirit or scope of the present invention. Accordingly, such changes and modifications are construed as within the scope of the invention as defined from the scope of the claims.

1: A resin composition, comprising:
a thermoplastic liquid crystal polymer,
wherein the resin composition has a dielectric dissipation factor of 0.0015 or less at 5 GHz, and has a percent decrease of a complex viscosity η* of 20% or less, where
the complex viscosity η* is measured using a rotational rheometer following parallel plate measurement with a gap distance of 0.9 mm and plate diameter of 25 mm at a strain of 3.0% and a measurement temperature of Tm₁+20° C., in which Tm₁ denotes an endothermic peak temperature attributed to the thermoplastic liquid crystal polymer measured using a differential scanning calorimeter; soak time during each measurement at frequencies of 1 rad/s and 100 rad/s is 0.0 seconds; sampling interval during the measurement at the frequency of 100 rad/s is 5.0 s/pt; and preheating time is 5 minutes, and
the percent decrease of the complex viscosity η* is calculated from a value measured at a point when a frequency of the rotational rheometer is changed to 100 rad/s following 12 minutes of an operation at 1 rad/s, and a value measured 7 minutes after the point of frequency change.

2: The resin composition according to claim 1, wherein the resin composition has a melt viscosity of 30 to 120 Pa·s, where the melt viscosity is measured using a capillary rheometer under the following conditions: a capillary diameter of 1.0 mm, a capillary length of 20 mm, a temperature of the endothermic peak temperature Tm₁+20° C., a shear rate of 1000 sec⁻¹, and a preheating time of 5 minutes.

3: The resin composition according to claim 1, wherein the resin composition has a melt tension of 0.002 N or more, where the melt tension is measured using a capillary rheometer by taking up the resin composition at a speed of 30 m/min, with a distance from a capillary outlet to a center position of a tension pulley set at 200 mm, under the following conditions: a capillary diameter of 1.0 mm, a capillary length of 20 mm, a temperature of the endothermic peak temperature Tm₁+20° C., a shear rate of 1000 sec⁻¹, and a preheating time of 5 minutes.

4: The resin composition according to claim 1, wherein the resin composition has a difference between Tm₁ and Tm₆ (Tm₁−Tm₆), of 12° C. or less, where Tm₁ denotes an endothermic peak temperature during a first heating run and Tm₆ denotes an endothermic peak temperature during a sixth heating run, when a heating and cooling cycle is repeated using a differential scanning calorimeter under a heating condition where a temperature is increased from 25° C. to 400° C. at a rate of 20° C./min and is maintained for 2 minutes after the temperature reaches 400° C. and a cooling condition where the temperature is decreased from 400° C. to 25° C. at a rate of 20° C./min and is maintained for 2 minutes after the temperature reaches 25° C.

5: The resin composition according to claim 1, wherein the resin composition has a ratio Y/X of 1.30 or less, where X denotes a melt viscosity (Pa·s) measured using a capillary rheometer under the following conditions: a capillary diameter of 1.0 mm, a capillary length of 20 mm, a temperature of the endothermic peak temperature Tm₁+20° C., a shear rate of 1000 sec⁻¹, and a preheating time of 5 minutes, and Y denotes a melt viscosity (Pa·s) subsequently measured under conditions of the same temperature and shear rate after the resin composition is allowed to stand at the same temperature in a barrel of the capillary rheometer for 30 minutes.

6: The resin composition according to claim 1, wherein based on a total content of all repeating units in the thermoplastic liquid crystal polymer, a molar proportion of a repeating unit represented by the following formula (1) is 0 to 25 mol %, a molar proportion of a repeating unit represented by the following formula (2) is 25 to 90 mol %, a molar proportion of a repeating unit represented by the following formula (3) is 0.1 to 40 mol %, and a molar proportion of a repeating unit represented by the following formula (4) is 0.1 to 40 mol %; 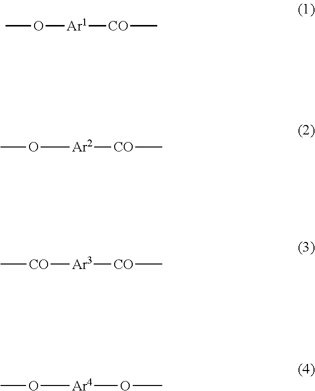
where
Ar¹ is a 1,4-phenylene group,
Ar² is a 2,6-naphthylene group,
Ar³ is at least one selected from the group consisting of a 1,4-phenylene group, a 1,3-phenylene group, and a 2,6-naphthylene group,
Ar⁴ is at least one selected from the group consisting of a 1,4-phenylene group, a 1,3-phenylene group, and a 4,4′-biphenylylene group, and
hydrogen atoms of aromatic rings of Ar¹, Ar², Ar³, and Ar⁴ are each optionally independently substituted with at least one selected from the group consisting of a C₁₋₃ alkyl group, a halogen atom, and a phenyl group.

7: The resin composition according to claim 6, wherein the thermoplastic liquid crystal polymer contains a total of 40 mol % or more of a repeating unit including a 2,6-naphthylene group based on the total content of all the repeating units.

8: The resin composition according to claim 1, further comprising particulate materials.

9: The resin composition according to claim 1, further comprising an additive material, wherein the additive material is at least one selected from the group consisting of a thermoplastic resin, a thermosetting resin, an inorganic compound, and a liquid crystalline oligomer.

10: The resin composition according to claim 9, wherein the additive material comprises a thermoplastic resin, which is at least one selected from the group consisting of an amorphous polyarylate-based resin, a polyphenylene ether-based resin, a polyphenylene sulfide-based resin, a polyetherimide-based resin, a polyether sulfone-based resin, a polycarbonate-based resin, a polyether ether ketone-based resin, and a fluorine-based resin.

11: The resin composition according to claim 9, wherein the additive material comprises an inorganic compound, which is at least one selected from the group consisting of silica and titanium oxide.

12: The resin composition according to claim 9, wherein the additive material comprises two or more types of inorganic particles having different median diameters from each other.

13: The resin composition according to claim 9, comprising two or more types of the additive material.

14: The resin composition according to claim 9, wherein a weight ratio of the thermoplastic liquid crystal polymer to the additive material is in a range of from 63.0/37.0 to 94.9/5.1.

15: A film, comprising:
the resin composition according to claim 1.

16: The film according to claim 15, having a thickness of 5 to 200 μm.

17: The film according to claim 15, having a coefficient of variation of thickness in a film width direction of 1.90% or less as measured using a continuous thickness gauge.

18: A metal-clad laminate, comprising:
the film according to claim 15 and
a metal layer bonded to at least one surface of the film.

19: A circuit board, comprising:
a conductor layer, and
an insulating layer containing the resin composition according to claim 1.
